(19) United States
(12) Patent Application Publication
(10) Pub. No.: US 2026/0018465 A1
(43) Pub. Date: Jan. 15, 2026

(54) METHOD OF MANUFACTURING ELECTRONIC DEVICE

(71) Applicant: Innolux Corporation, Miaoli County (TW)

(72) Inventors: Chao-Jen Chen, Miaoli County (TW); Chien-Hsing Lee, Miaoli County (TW); Shih-Jung Teng, Miaoli County (TW); Chun-Hung Chen, Miaoli County (TW)

(73) Assignee: Innolux Corporation, Miaoli County (TW)

(21) Appl. No.: 19/239,957

(22) Filed: Jun. 17, 2025

Related U.S. Application Data
(60) Provisional application No. 63/669,700, filed on Jul. 11, 2024.

(30) Foreign Application Priority Data
Mar. 5, 2025 (CN) 202510257101.5

(51) Int. Cl. H01L 21/78; H01L 23/544

(52) U.S. Cl. CPC H01L 21/78; H01L 23/544; H01L 2223/54426

(57) ABSTRACT

The disclosure provides a method of manufacturing an electronic device. The method of manufacturing the electronic device includes the following steps: providing a transparent carrier having an accommodation space, wherein the transparent carrier has a first mark; disposing a sample in the accommodation space of the transparent carrier, wherein the sample has a second mark; calculating an offset of the sample according to the first mark, the second mark, and a standard value; and forming a third mark on the sample or the transparent carrier according to the offset. The method of manufacturing of the electronic device of the disclosure may improve process yield or reliability.

### CROSS-REFERENCE TO RELATED APPLICATION

This application claims the priority benefits of U.S. provisional application Ser. No. 63/669,700, filed on Jul. 11, 2024, and China application serial no. 202510257101.5, filed on Mar. 5, 2025, The entirety of each of the above-mentioned patent applications is hereby incorporated by reference herein and made a part of this specification.

### BACKGROUND

### Technical Field

The disclosure relates to a method of manufacturing an electronic device, and more particularly to a method of manufacturing an electronic device capable of improving process yield or reliability.

### Description of Related Art

Electronic devices or tiled electronic devices have been widely used in different fields such as communication, display, automotive, or aviation. With the rapid development of electronic devices, electronic devices are being developed to be thinner and lighter. Therefore, the requirements for reliability or quality of electronic devices are getting higher.

### SUMMARY

The disclosure is directed to a method of manufacturing an electronic device that may improve process yield or reliability.

According to an embodiment of the disclosure, a method of manufacturing an electronic device includes the following steps: providing a transparent carrier having an accommodation space, wherein the transparent carrier has a first mark; disposing a sample in the accommodation space of the transparent carrier, wherein the sample has a second mark; calculating an offset of the sample according to the first mark, the second mark, and a standard value; and forming a third mark on the sample according to the offset.

According to an embodiment of the disclosure, a method of manufacturing an electronic device includes the following steps: providing a transparent carrier having an accommodation space, wherein the transparent carrier has a first mark; disposing a sample in the accommodation space of the transparent carrier, wherein the sample has a second mark; calculating an offset of the sample according to the first mark, the second mark, and a standard value; and forming a third mark on the transparent carrier according to the offset.

### BRIEF DESCRIPTION OF THE DRAWINGS

FIG. 1 is a flowchart of a method of manufacturing an electronic device of the first embodiment of the disclosure.

FIG. 2 is a partial three-dimensional view of steps S1 to S6 in the method of manufacturing the electronic device of FIG. 1.

FIG. 3 is a partial cross-sectional view of a method of manufacturing the electronic device of FIG. 2.

FIG. 4 is a schematic top view of step S3 in the method of manufacturing the electronic device of FIG. 1.

FIG. 5A is a schematic top view of steps S4 to S5 in the method of manufacturing the electronic device of FIG. 1.

FIG. 5B is a schematic top view of steps S4 to S5 in the method of manufacturing the electronic device of FIG. 1.

FIG. 5C is a schematic top view of steps S4 to S5 in the method of manufacturing the electronic device of FIG. 1.

FIG. 6A to FIG. 6C are cross-sectional views of steps S6 to S7 in the method of manufacturing the electronic device of FIG. 1.

FIG. 7A to FIG. 7B are cross-sectional views of steps S6 to S7 of the method of manufacturing the electronic device of the second embodiment of the disclosure.

FIG. 8 is a schematic cross-sectional view of the electronic device of the third embodiment of the disclosure.

### DESCRIPTION OF THE EMBODIMENTS

The disclosure may be understood by referring to the following detailed description in conjunction with the accompanying drawings. It should be noted that in order to facilitate understanding to the reader and to simplify the drawings, the multiple drawings in the disclosure depict a portion of the electronic device, and certain elements in the drawings are not drawn to actual scale. In addition, the number and size of each element in the figures are for illustration and are not intended to limit the scope of the disclosure.

In the following description and claims, words such as “including” and “comprising” are open-ended words, and thus should be interpreted as meaning “including but not limited to . . . ”

It should be understood that, when an element or film is referred to as being “on” or “connected to” another element or film, the element or film may be directly on or directly connected to this other element or layer, or there may be an intervening element or layer in between (indirect case). In contrast, when an element is referred to as being “directly on” or “directly connected to” another element or layer, there are no intervening elements or layers present between the two.

Although the terms “first”, “second”, “third” . . . may be used to describe various constituent elements, the constituent elements are not limited to these terms. These terms are used to distinguish a single constituent element from other constituent elements in the specification. The same terms may be omitted in the claims and instead replaced with first, second, third . . . according to the order in which the elements are declared in the claims. Therefore, in the following description, a first constituent element may be a second constituent element in a claim.

In this article, the terms “about”, “approximately”, “substantially”, “essentially” usually mean within 10%, or within 5%, or within 3%, or within 2%, or within 1%, or within 0.5% of a given value or range. The quantities given here are approximate quantities, that is, without specific instructions such as “about”, “approximately”, “substantially”, “essentially”, the meanings of “about”, “approximately”, “substantially”, “essentially” may still be implied.

In some embodiments of the disclosure, terms related to joining, connecting, such as “connecting”, “interconnecting”, etc., unless otherwise specified, may mean that two structures are in direct contact, or it may also mean that the two structures are not in direct contact, and there are other structures disposed between the two structures. Furthermore, the terms joined and connected may also include situations in which both structures are movable, or both structures are fixed. In addition, the term “coupling” includes any direct and indirect connection means.

In some embodiments of the disclosure, optical microscopy (OM), scanning electron microscope (SEM), film thickness profiler (α-step), ellipsometer, or other suitable methods may be used to measure the area, width, thickness, or height of each element, or the distance or spacing between the elements. Specifically, according to some embodiments, a scanning electron microscope may be used to obtain a cross-sectional structure image including the elements to be measured, and measure the area, width, thickness, or height of each element, or the distance or spacing between the elements.

In some embodiments of the disclosure, the surface roughness may be measured by using an electron microscope such as a scanning electron microscope or a transmission electron microscope (TEM) to observe the surface undulations at the same appropriate magnification, and the undulations may be compared per unit length (e.g., 10 microns). Appropriate magnification means that at least one surface may have a roughness or an average roughness of at least 10 undulating peaks visible under the field of view of this magnification. Each layer shown in the drawings of the disclosure may have a rough surface. It should be noted that the rough surface of each layer may refer to the ups and downs of the surface of each layer in a cross-sectional view observed via an electron microscope.

In the disclosure, an electronic device may include a power module, a semiconductor device, a semiconductor packaging device, a display device, a light-emitting device, a backlight device, a virtual reality device, an augmented reality (AR) device, an antenna device, a sensing device, a tiling device, or any combination thereof, but the disclosure is not limited thereto. The display device may be a non-self-luminous display or a self-luminous display according to requirements, and may be a color display or a monochrome display according to requirements. The antenna device may be a liquid-crystal-type antenna device or a non-liquid-crystal-type antenna device, and the sensing device may be a sensing device sensing capacitance, light, heat energy, or ultrasonic waves, the tiling device may be a display tiling device or an antenna tiling device, but the disclosure is not limited thereto. The electronic unit in the electronic device may include a semiconductor element, a passive element, and an active element, such as an integrated circuit chip, a high-bandwidth memory, a capacitor, a resistor, an inductor, a diode, a micro-electromechanical system element (MEMS), a transistor, etc. The diode may include a light-emitting diode (LED) or a photodiode. The LED may include, for example, an organic light-emitting diode (OLED), a mini LED, a micro-LED, or a quantum dot LED (QDLED), but the disclosure is not limited thereto. The transistor may include, for example, a top-gate thin-film transistor, a bottom-gate thin-film transistor, or a dual-gate thin-film transistor, but the disclosure is not limited thereto. The electronic device may also include a fluorescent material, a phosphor material, a quantum dot (QD) material, or other suitable materials according to requirements, but the disclosure is not limited thereto. The electronic device may have a peripheral system such as a drive system, a control system, a light source system, etc. to support a display device, an antenna device, a wearable device (for example, including an augmented reality or virtual reality device), a vehicle-mounted device (for example, including a car windshield), or a tiling device. It should be noted that the electronic device may be any combination of the above, but the disclosure is not limited thereto. The following takes an electronic device as an example to illustrate the disclosure, but the disclosure is not limited thereto. The sensor may include, for example, a capacitive sensor, an optical sensor, an electromagnetic sensor, a fingerprint sensor (FPS), a touch sensor, an antenna, or a pen sensor, but the disclosure is not limited thereto. According to an embodiment of the disclosure, the provided method of manufacturing the electronic device may be applied, for example, to a wafer-level package (WLP) process or a panel-level package (PLP) process, and may adopt a chip-first process or a chip-last (RDL first) process, which will be explained in further detail below. The electronic device referred to in the disclosure may include system-on-package (SoC), system-in-package (SiP), antenna-in-package (AiP), co-packaged optics (CPO), or a combination of the above, but the disclosure is not limited thereto.

It should be noted that in the following embodiments, the features in several different embodiments may be replaced, recombined, and mixed to complete other embodiments without departing from the spirit of the disclosure. Features in various embodiments may all be mixed and matched as long as they do not violate the spirit of the disclosure or conflict with each other.

Reference will now be made in detail to the exemplary embodiments of the disclosure, examples of which are illustrated in the accompanying drawings. Wherever possible, the same reference numerals are used in the drawings and descriptions to refer to the same or like portions.

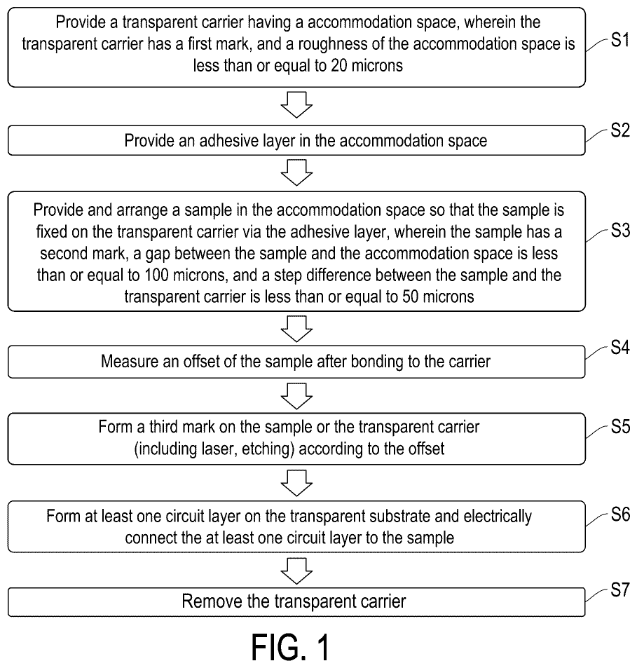

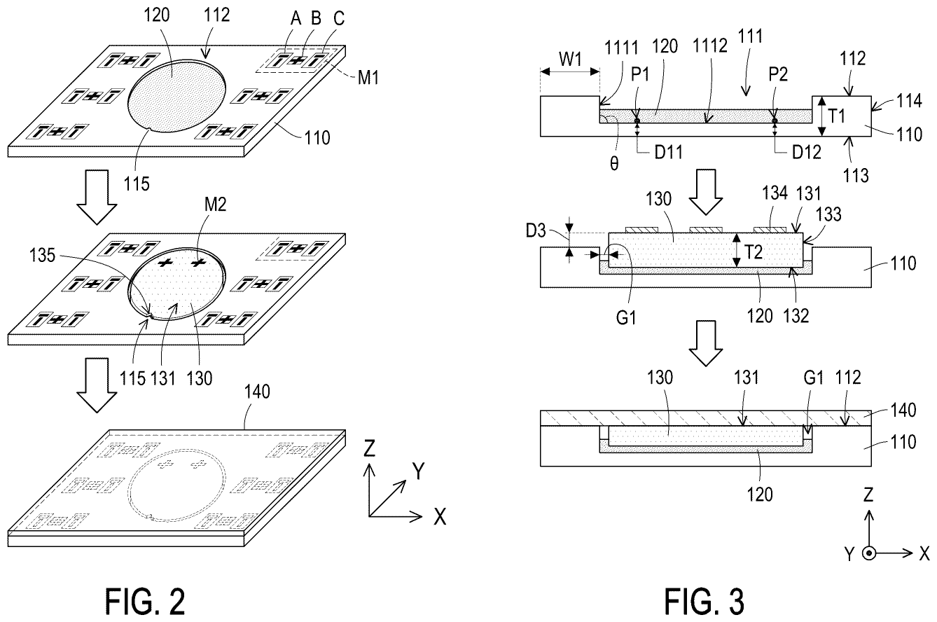

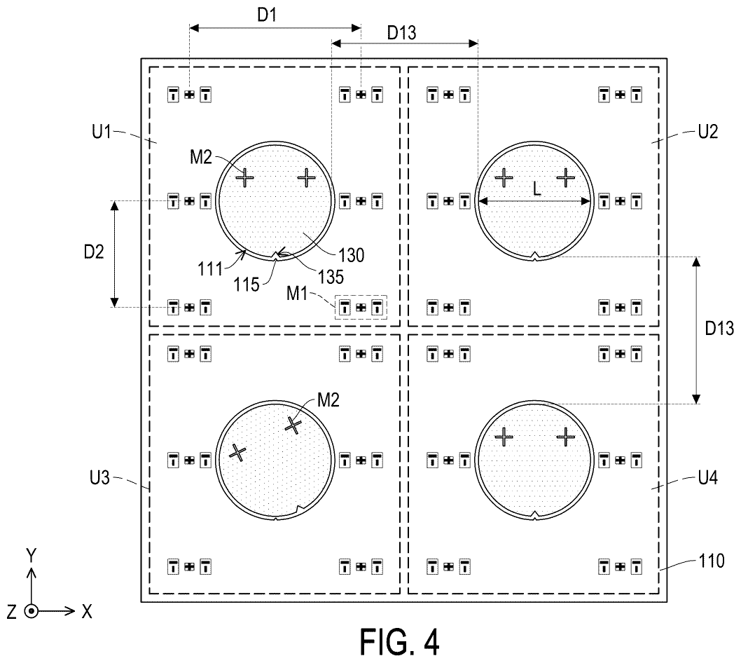

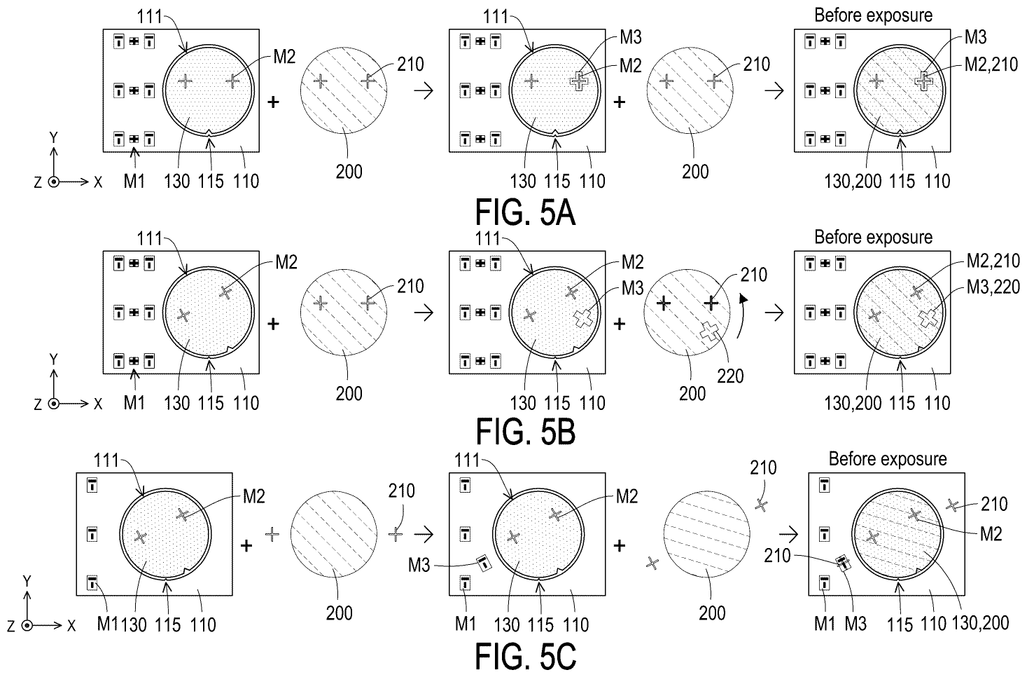

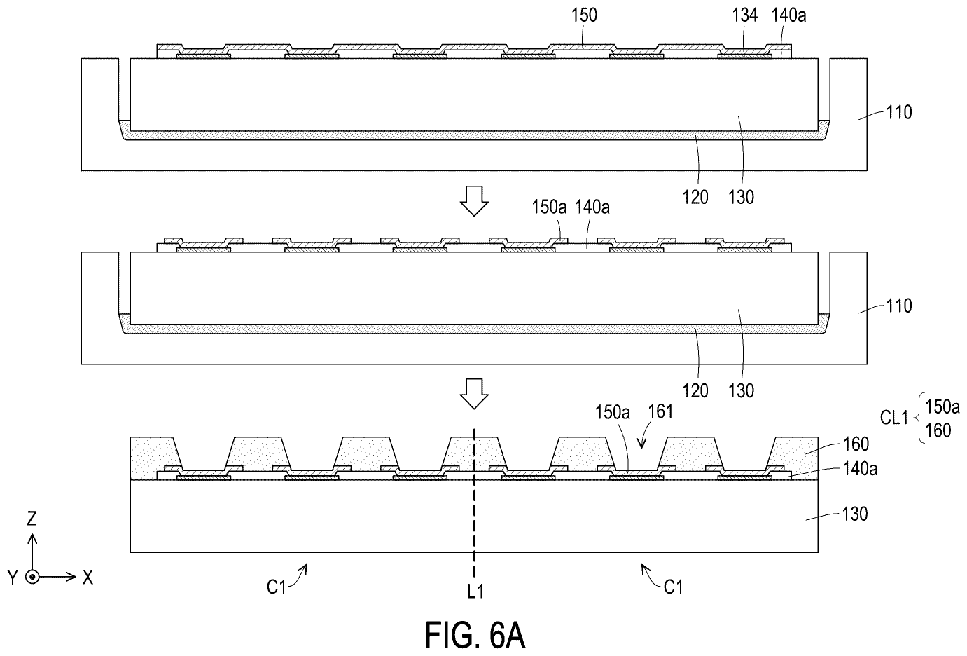

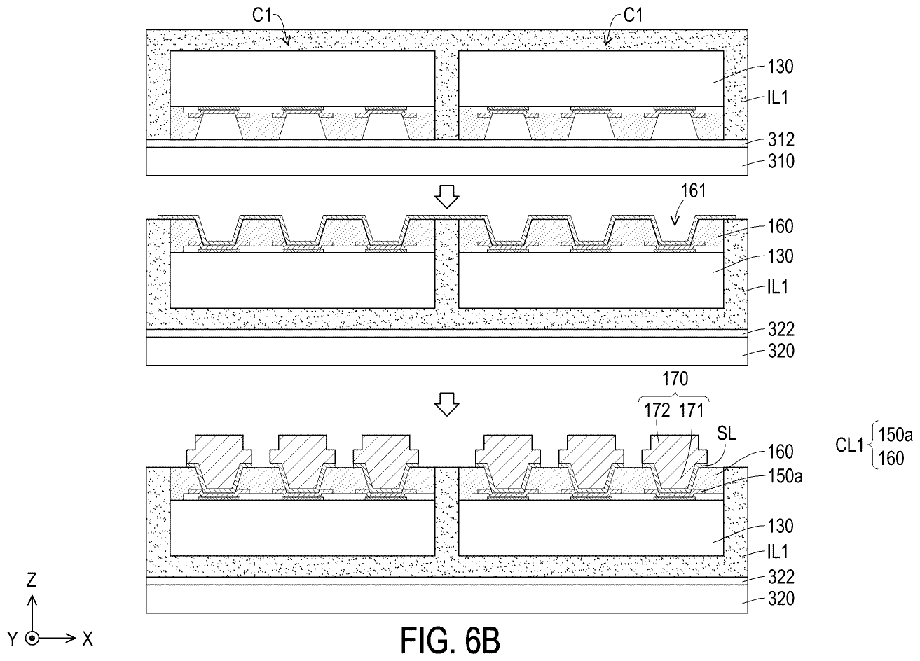

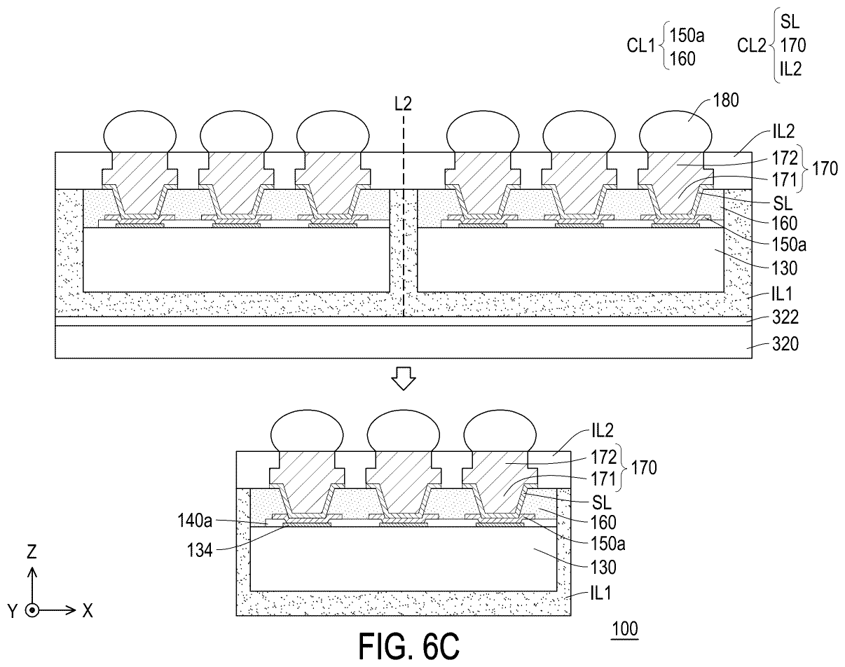

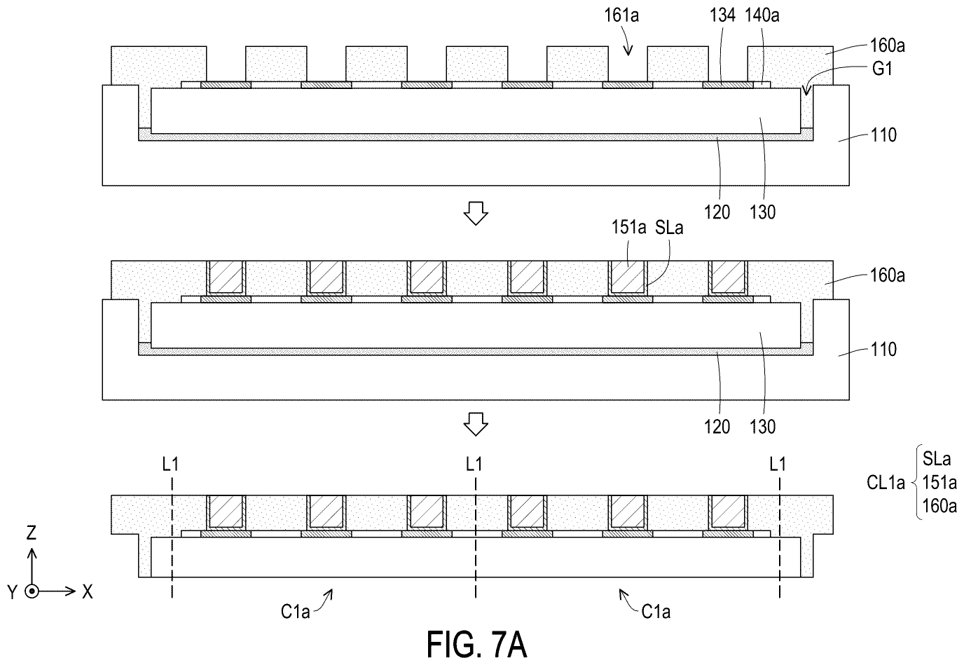

FIG. 1 is a flowchart of a method of manufacturing an electronic device of the first embodiment of the disclosure. FIG. 2 is a partial three-dimensional view of steps S1 to S6 in the method of manufacturing the electronic device of FIG. 1. FIG. 3 is a partial cross-sectional view of a method of manufacturing the electronic device of FIG. 2. FIG. 4 is a schematic top view of step S3 in the method of manufacturing the electronic device of FIG. 1. FIG. 5A is a schematic top view of steps S4 to S5 in the method of manufacturing the electronic device of FIG. 1. FIG. 5B is a schematic top view of steps S4 to S5 in the method of manufacturing the electronic device of FIG. 1. FIG. 5C is a schematic top view of steps S4 to S5 in the method of manufacturing the electronic device of FIG. 1. FIG. 6A to FIG. 6C are cross-sectional views of steps S6 to S7 in the method of manufacturing the electronic device of FIG. 1. For clarity and convenience of description, some elements in the electronic device are omitted in FIG. 4, FIG. 5A, FIG. 5B, and FIG. 5C.

In the present embodiment, the manufacturing method of an electronic device 100 of the present embodiment may include the following steps.

Referring to FIG. 1 to FIG. 4, step S1 is first performed to provide a transparent carrier 110 having an accommodation space 111. Specifically, in the present embodiment, the material of the transparent carrier 110 may include quartz, glass, sapphire, polyetheretherketone (PEEK), Teflon (PTFE), other suitable materials, or a combination thereof, but the disclosure is not limited thereto. In particular, polyetheretherketone and Teflon are resistant to acid and alkali, heat (temperature of about 250 degrees) and anti-static (static electricity of about 100 volts or less).

In the present embodiment, the transparent carrier 110 may be a carrier having high light transmittance, so that the transparent carrier 110 may remove the photo-degradable release layer by bottom illumination in a subsequent process, thereby reducing the issue of carrier warping caused by repeated heating due to the use of a thermally degradable release layer, but the disclosure is not limited thereto. In the present embodiment, the light transmittance (ex.: for UV light) of the transparent carrier 110 may be 85% or more, 90% or more, or 95% or more, but the disclosure is not limited thereto.

In the present embodiment, the transparent carrier 110 further has a surface 112, a surface 113, a side surface 114, a protrusion 115, and a first mark M1. The surface 112 and the surface 113 are opposite to each other, and the side surface 114 is connected to the surface 112 and the surface 113. The protrusion 115 is protruded toward the accommodation space 111, so as to be used as an alignment mark when the sample 130 is subsequently disposed in the accommodation space 111 of the transparent carrier 110 to improve the mounting accuracy of the sample 130. In the present embodiment, a thickness T1 of the transparent carrier 110 may be greater than or equal to 1.3 mm and less than or equal to 3 mm (i.e., 1.3 mm≤T1≤3 mm) to reduce the probability of bending or damage of the transparent carrier 110, but the disclosure is not limited thereto. A width W1 of the edge of the transparent carrier 110 (i.e., the area not overlapped with the accommodation space 111 when viewed from above) may be between 50 microns (μm) and 3000 μm (i.e., 50 μm≤W1≤3000 μm), 100 μm to 2000 μm, or 500 μm to 1500 μm to avoid cracking of the carrier due to insufficient supporting force. In particular, the thickness T1 may be the distance between the surface 112 and the surface 113 measured along a direction Z (the normal direction of the transparent carrier 110); the width W1 may be the distance between an inner wall 1111 of the accommodation space 111 and a side surface 114 of the transparent carrier 110 measured along a direction X or a direction Y. According to some embodiments, the overall thickness variation of the transparent carrier 110 may be less than 50 microns, or less than 30 microns, or less than 10 microns, thereby reducing the impact on circuit offset, but the disclosure is not limited thereto. The thickness variation referred to in the disclosure refers to the thickness of the transparent carrier 110 measured at at least five locations along the normal direction (the direction Z) of the transparent carrier 110, and the thickness variation (variance, σ) is calculated by statistical calculation.

In the present embodiment, the direction X, the direction Y, and the direction Z are different directions. The direction Z may be a normal direction of the transparent carrier 110, and the direction Z may be perpendicular to the direction X and the direction Y respectively, and the direction X may be perpendicular to the direction Y, but the disclosure is not limited thereto.

In the present embodiment, the first mark M1 is disposed on the surface 112, but the disclosure is not limited thereto. According to some embodiments, the first mark M1 may also be disposed in the transparent carrier 110, that is, the first mark M1 is disposed between the surface 112 and the surface 113. The first mark M1 may be manufactured, for example, by using a photolithography process, wherein the photolithography process may include providing a laser having a wavelength greater than or equal to 390 nanometers (nm) and less than or equal to 1075 nanometers, but the disclosure is not limited thereto. The first mark M1 may include at least one mark. For example, the first mark M1 may include three marks (i.e., a mark A, a mark B, and a mark C) arranged along the direction X, wherein the pattern of the mark A is the same as the pattern of the mark C, and the pattern of the mark B is different from the pattern of the mark A and the pattern of the mark C, but the disclosure is not limited thereto. In some embodiments, the number and the pattern of the marks in the first mark M1 may be adjusted according to the design requirements of the product.

In the present embodiment, the accommodation space 111 may be provided by, for example, computer numerical control (CNC) by automatically controlling a machining tool and a 3D printer via a computer. According to some embodiments, the accommodation space 111 may also be formed into a groove recessed inwardly of the surface 112 by a method such as laser, etching, so as to be used for placing a sample in a subsequent process. The accommodation space 111 has an inner wall 1111 and a bottom surface 1112. The roughness of the bottom surface 1112 of the accommodation space 111 may be different from the roughness of the surface 112 of the transparent carrier 110. In the present embodiment, along the normal direction (the direction Z) of the transparent carrier 110, the distances between any two different positions (e.g., a point P1 and a point P2) of the bottom surface 1112 of the accommodation space 111 and the surface 113 of the transparent carrier 110 are respectively D11 and D12, and the absolute value of the difference between the distance D11 and the distance D12 may be less than or equal to 1 micron (i.e., |D11−D12|≤1 μm). In the present embodiment, the roughness of the bottom surface 1112 of the accommodation space 111 may be less than or equal to 20 microns, so that the sample placed in the accommodation space 111 has better flatness in a subsequent process. In the present embodiment, as shown in the cross-sectional view of FIG. 3, the profile shape of the accommodation space 111 may be a rectangle, but the disclosure is not limited thereto. In some embodiments, the profile shape of the accommodation space may also be a trapezoid or an inverted trapezoid (as shown in FIG. 6A). In some embodiments, there is an included angle θ between an extension line of the bottom surface 1112 of the accommodation space 111 and an extension line of the inner wall 1111, and the included angle θ may be between 75 degrees and 150 degrees (i.e., 75°≤θ≤150°), but the disclosure is not limited thereto. According to some embodiments, the included angle θ has an arc-shaped profile, as shown in FIG. 6A.

In the present embodiment, the transparent carrier 110 may include a plurality of units. As shown in FIG. 4, four units (i.e., a unit U1, a unit U2, a unit U3, and a unit U4) are schematically shown. However, the disclosure does not limit the number of units. In particular, FIG. 2 and FIG. 3 may be regarded as the manufacturing process of the unit U1, the unit U2, or the unit U4. Referring to FIG. 4, taking the unit U1 as an example, the unit U1 includes an accommodation space 111 and a plurality of first marks M1. The plurality of first marks M1 may be respectively disposed at the upper side, the middle side, and the lower side of the left and right sides of the transparent carrier 110 to surround the accommodation space 111, but the disclosure is not limited thereto. In the present embodiment, the distance D1 between two adjacent first marks M1 in the X direction may be 60 mm to 420 mm (i.e., 60 mm≤D1≤420 mm), and the distance D2 between two adjacent first marks M1 in the Y direction may be 100 mm to 300 mm (i.e., 100 mm≤D2≤300 mm), but the disclosure is not limited thereto. In particular, the distance D1 may be the distance measured along the direction X between the cross center (or geometric center, or the same side) of one of the first marks M1 and the cross center (or geometric center, or the same side) of another adjacent first mark M1, and the distance D2 may be the distance measured along the direction Y between the cross center (or geometric center, or the same side) of one of the first marks M1 and the cross center (or geometric center, or the same side) of another adjacent first mark M1.

Then, referring to FIG. 1 to FIG. 4, step S2 is performed to provide an adhesive layer 120 in the accommodation space 111. Specifically, the adhesive layer 120 may be a temporary adhesive layer and include an optical-type release material or a thermal-type release material having adhesiveness, so that a subsequently formed working unit, element, or layer may be temporarily bonded on the adhesive layer 120. For example, the adhesive layer 120 may be a light-to-heat-conversion (LTHC) release coating or a thermal release tape (HRT). When the optical release material is used as the adhesive layer 120 and is exposed to radiation such as ultraviolet light (UV light), the optical release material loses viscosity, so that the element or layer formed thereon may be peeled off from the adhesive layer 120.

Then, step S3 is performed to provide and arrange the sample 130 in the accommodation space 111 of the transparent carrier 110. Specifically, the sample 130 may be grasped, moved, rotated, or the like via an equipment or a tool to change the position and be fixed on the transparent carrier 110 via the adhesive layer 120, and a portion of the adhesive layer 120 may be squeezed into a gap G1 between the sample 130 and the accommodation space 111 to reduce the probability of collision between the sample 130 and the transparent carrier 110. In the present embodiment, the sample 130 may be a wafer, but the disclosure is not limited thereto.

In addition, please continue to refer to FIG. 4, the sample 130 has a maximum length L, and a minimum distance D13 between two adjacent samples 130 may be greater than or equal to 2 mm and less than or equal to twice the maximum length L of the sample 130 (i.e., 2 mm≤D13≤2×L), but the disclosure is not limited thereto. In particular, the maximum length L may be the maximum length of the sample 130 measured along the direction X; the minimum distance D13 may be the minimum distance measured along the direction X between the sample 130 in the unit U1 and the sample 130 in the unit U2, or may be the minimum distance measured along the direction Z between the sample 130 in the unit U2 and the sample 130 in the unit U4.

In the present embodiment, the sample 130 has a surface 131, a surface 132, a side surface 133, at least one pad 134, a notch 135, and a second mark M2. The surface 131 and the surface 132 are opposite to each other, and the side surface 133 is connected to the surface 131 and the surface 132. The at least one pad 134 is disposed on the surface 131. The notch 135 is not in contact with the protrusion 11, but the notch 135 may be aligned with the protrusion 115 to improve the accuracy of mounting the sample 130. In the present embodiment, a thickness T2 of the sample 130 may be greater than or equal to the thickness T1 of the transparent carrier 110, and the thickness T2 of the transparent carrier 110 may be ⅓ to 1 time the thickness T1 of the sample 130 (i.e., ⅓×T1<T2≤T1), but the disclosure is not limited thereto. In particular, the thickness T2 may be the distance measured along the direction Z between the surface 131 and the surface 132. In addition, in the present embodiment, the ratio of a coefficient of thermal expansion CTE1 of the transparent carrier 110 to a coefficient of thermal expansion CTE2 of the sample 130 is 0.7 to 3 (i.e., 0.7≤CTE1/CTE2≤3), 0.7≤CTE1/CTE2≤2, or 0.8≤CTE1/CTE2≤1.8. Via the above design, the risk of sample cracking caused by the mismatch of the coefficients of thermal expansion of the two may be reduced.

In the present embodiment, there is the gap G1 between the side surface 133 of the sample 130 and the inner wall 1111 of the accommodation space 111, and the gap G1 may be greater than 0 microns and less than or equal to 100 microns (i.e., 0 μm≤G1≤100 μm) to reduce the issue of cracking due to excessive step difference during the subsequent forming of the dielectric layer, or reduce the probability of collision between the sample 130 and the transparent carrier 110, thereby improving process yield or reliability, but the disclosure is not limited thereto. In particular, the gap G1 may be the distance between the side surface 133 of the sample 130 and the inner wall 1111 of the accommodation space 111 measured along the direction X or the direction Y.

In the present embodiment, a leveling step is then performed on the sample 130, such as moving from a direction away from the transparent carrier 110 to a direction close to the transparent carrier 110 via a platform, and a pressure P-1 is applied to the sample 130 for leveling. After the leveling step, there is a step D3 between the surface 131 of the sample 130 and the surface 112 of the transparent carrier 110, and the step D3 may be greater than 0 microns and less than or equal to 50 microns (i.e., 0 μm≤D3≤50 μm) to reduce the issue of cracking caused by excessive step when the dielectric layer is subsequently formed, thereby improving process yield or reliability, but the disclosure is not limited thereto. In particular, the step D3 may be the distance measured along the direction Z between the surface 131 of the sample 130 and the surface 112 of the transparent carrier 110. According to some embodiments, a detection step may be performed after the leveling step to determine whether the step difference D3 meets the specifications. If the step difference D3 does not meet the specifications, that is, the step difference D3 is greater than 50 μm, a re-leveling step needs to be performed, wherein a pressure P-2 applied in the re-leveling step is less than the pressure P-1 to avoid cracking of the sample 130 or other risks.

Then, step S4 and step S5 are performed. Before photolithography is performed, the offset of the sample 130 is calculated according to the first mark M1, the second mark M2, and the standard value, and a third mark M3 is formed on the sample 130 or the transparent carrier 110 according to the offset. Specifically, after the sample 130 is attached to the accommodation space 111 of the transparent carrier 110, first, the coordinate difference and the rotation angle between the second mark M2 of the sample 130 and the first mark M1 of the transparent carrier 110 are measured by, for example, a detection machine or a test machine; then, the measured coordinate difference and rotation angle are compared with the standard value to calculate the offset of the sample 130; then, the third mark M3 is formed on the sample 130 (for example, formed on an area of the sample 130 not passing the yield test) (as shown in FIG. 5B) or on the transparent carrier 110 (as shown in FIG. 5C) according to the offset. In the present embodiment, the offset includes, for example, a coordinate difference and a rotation angle, but the disclosure is not limited thereto.

More specifically, please refer to FIG. 4 and FIG. 5A. In the unit U1, the unit U2, or the unit U4, when the offset is equal to 0 or within the allowable range, the third mark M3 formed on the sample 130 may be overlapped with the second mark M2, and then without adjusting the position and repositioning a preset mask 200, a lithography positioning point 210 of the preset mask 200 may be overlapped with the second mark M2 before the exposure step is performed. In particular, the preset mask 200 may be used to form a conductive pattern or other patterns needed by the sample 130, but the disclosure is not limited thereto.

Please refer to FIG. 4 and FIG. 5B. In the unit U3, when the offset is not equal to 0 or exceeds the allowable range, the third mark M3 formed on the sample 130 is not overlapped with the second mark M2, and then the preset mask 200 needs to be adjusted and repositioned according to the offset. Referring to FIG. 5B, for example, the preset mask 200 may be rotated so that the lithography positioning point 210 and a repositioning point 220 of the preset mask 200 may be overlapped with the second mark M2 and the third mark M3 respectively before the exposure step. In some embodiments, the transparent carrier 110 may be adjusted and repositioned so that the photolithography positioning point 210 and the repositioning point 220 of the preset mask 200 may be overlapped with the second mark M2 and the third mark M3 respectively before the exposure step. In some embodiments, in a photolithography process without using a preset mask, a new exposure pattern may be produced according to the third mark M3 by using, for example, an exposure machine or a photolithography machine. Therefore, the accuracy of alignment may be improved by correcting the offset, so as to improve process yield or reliability.

Please refer to FIG. 4 and FIG. 5C. In the unit U3, when the offset is not equal to 0 or exceeds the allowable range, the third mark M3 formed on the transparent carrier 110 is not overlapped with the first mark M1, and then the preset mask 200 needs to be adjusted and repositioned according to the offset so that the lithography positioning point 210 of the preset mask 200 may be overlapped with the third mark M3 before the exposure step. In some embodiments, the transparent carrier 110 may be adjusted and repositioned so that the photolithography positioning point 210 of the preset mask 200 may be overlapped with the third mark M3 before the exposure step is performed. In some embodiments, in a photolithography process without using a preset mask, a new exposure pattern may be produced according to the third mark M3 using, for example, an exposure machine. Therefore, the accuracy of alignment may be improved by correcting the offset, so as to improve process yield or reliability.

Then, referring to FIG. 1 to FIG. 3 and FIG. 6A to FIG. 6C, step S6 is performed to form at least one circuit layer CL1 on the transparent carrier 110, and the at least one circuit layer CL1 may be electrically connected to the sample 130.

Specifically, first, a dielectric layer 140 is provided on the sample 130 and the transparent carrier 110. In particular, the dielectric layer 140 may cover the surface 112 of the transparent carrier 110, the gap G1, and the surface 131 of the sample 130. In the present embodiment, the dielectric layer 140 is formed by a suitable method such as coating, deposition, lamination, etc., and the material of the dielectric layer 140 may include silicon oxide, silicon nitride, nitride, oxide, oxynitride, photosensitive polyimide (PSPI), Ajinomoto build-up layer (ABF), other suitable insulating materials, or a combination of the above, but the disclosure is not limited thereto. According to some embodiments, the thickness of the single dielectric layer 140 may be between 0.2 μm and 25 μm, wherein the dielectric loss factor (Df) of the dielectric layer 140 at an operating frequency of 10 GHz may be less than or equal to 0.007.

Next, referring to FIG. 6A, a patterning step is performed on the dielectric layer 140 via the third mark M3 to form a patterned dielectric layer 140a and expose the at least one pad 134 of the sample 130.

Next, referring to FIG. 6A, the connection material layer 150 is formed on the dielectric layer 140a, and the connection material layer 150 is patterned to form a connection unit 150a. In particular, the connection unit 150a may be in contact with the pad 134 of the sample 130 to be electrically connected to the sample 130. The connection unit 150a may expose a portion of the dielectric layer 140a. In the present embodiment, the connection unit 150a may be a copper column, but the disclosure is not limited thereto. In some embodiments, the activity ratio of the connection unit 150a may be less than the activity ratio of the pad 134 to reduce the reaction with a subsequently formed insulating layer 160.

Next, referring to FIG. 6A, an insulating layer 160 is formed on the connection unit 150a. In particular, the insulating layer 160 may cover the dielectric layer 140a. The insulating layer 160 has an opening 161, and the opening 161 may expose a portion of the connection unit 150a.

By now, the circuit layer CL1 (including the connection unit 150a and the insulating layer 160) is formed on the dielectric layer 140a and the pad 134.

Then, please continue to refer to FIG. 6A, step S7 is performed to perform a singulation step on the sample 130 (e.g., a wafer) to obtain a plurality of known good chips C1. Specifically, the singulation step may include: a step of removing the transparent carrier 110 and the adhesive layer 120, and a step of cutting along a cutting line L1 into the known good chips C1. In the present embodiment, the known good chips C1 are chips measured by an electrical signal, for example, a chip passing a short circuit or open circuit test. In addition, although in the present embodiment, the removing step is performed first and then the cutting step is performed, the cutting step includes knife cutting, laser cutting, or a combination thereof, but the disclosure is not limited thereto. In some embodiments, the order of the step of removing the transparent carrier 110 and the adhesive layer 120 and the step of cutting along the cutting line L1 into the known good chips C1 may be interchanged.

Then, referring to FIG. 6B, step S8 is performed to form at least one circuit layer CL2 on the circuit layer CL1, and the at least one circuit layer CL2 may be electrically connected to the sample 130 via the circuit layer CL1. In particular, the circuit layer CL1 is located between the circuit layer CL2 and the sample 130.

Specifically, first, referring to FIG. 6B, the two cut chips C1 are transferred to a carrier 310 having a release layer 312, and an insulating layer IL1 is formed on the chips C1. In particular, the two chips C1 are disposed on the release layer 312 in a flip-chip manner. The insulating layer IL1 may surround the chips C1. In the present embodiment, the material of the carrier 310 may be the same as or different from the material of the transparent carrier 110.

Next, referring to FIG. 6B, after the release layer 312 and the carrier 310 are removed, the substrate is flipped upside down and transferred to another carrier 320 having a release layer 322, and a seed layer SL is formed on the insulating layer 160 and in the opening 161. In particular, the seed layer SL may be in contact with the connection unit 150a to be electrically connected to the circuit layer CL1. The seed layer SL may expose a portion of the insulating layer 160.

Next, referring to FIG. 6B, a conductive layer 170 is formed on the seed layer SL and in the opening 161. In particular, the conductive layer 170 includes a connection portion 171 and a trace 172. The connection portion 171 may be a portion of the conductive layer 170 disposed in the opening 161 of the insulating layer 160 for signal transmission in the vertical direction. The trace 172 may be a portion other than the connection portion 171 for signal transmission in the horizontal direction. In the present embodiment, the material of the conductive layer 170 may include any suitable conductive material, such as copper (Cu), aluminum (Al), nickel (Ni), molybdenum (Mo), titanium (Ti), gold (Au), tin (Sn), gallium (Ga), ruthenium (Ru), tantalum (Ta), an alloy or combination of the above materials or other suitable materials, but the disclosure is not limited thereto.

Next, referring to FIG. 6C, an insulating layer IL2 is formed on the insulating layer IL1, and a connection member 180 is formed on the conductive layer 170. In particular, the insulating layer IL2 may cover the side surfaces of the insulating layer IL1, the insulating layer 160, and the trace 172. The connection member 180 may be in contact with the conductive layer 170. The connection member 180 may be overlapped with the sample 130 in the direction Z. In the present embodiment, the connection member 180 may be a solder ball, but the disclosure is not limited thereto. In some embodiments, the connection member 180 may also be a solder pad or chemical nickel gold.

By now, the circuit layer CL2 (including the seed layer SL, the conductive layer 170, and the insulating layer IL2) is formed on the circuit layer CL1.

In the present embodiment, the circuit layer CL1 and the circuit layer CL2 may be regarded as a portion of a redistribution layer (RDL), and the circuit layer CL1 and the circuit layer CL2 are fan-in circuit designs. In addition, in the present embodiment, in the process of forming the circuit layer CL1 and the circuit layer CL2, when the photolithography process is performed (for example, when forming a patterned dielectric layer, an insulating layer, or a connection unit, but the disclosure is not limited thereto), the four units (i.e., the unit U1, the unit U2, the unit U3, and the unit U4) may be exposed sequentially or simultaneously.

Then, referring to FIG. 6C, step S8 is performed to remove the transparent carrier 320 and the release layer 322, and cut the above along a cutting line L2 into a plurality of electronic devices 100.

In the present embodiment, the method of manufacturing the electronic device 100 may be applied to a 2.5D or 3D packaging technique, but the disclosure is not limited thereto.

Other examples are listed below as illustrations. It should be noted here that the following embodiments adopt the reference numerals and a portion of the content of the above embodiments, wherein the same reference numerals are used to represent the same or similar elements, and the description of the same technical content is omitted. For descriptions of omitted portions, reference may be made to the above embodiments and are not repeated in the following embodiments.

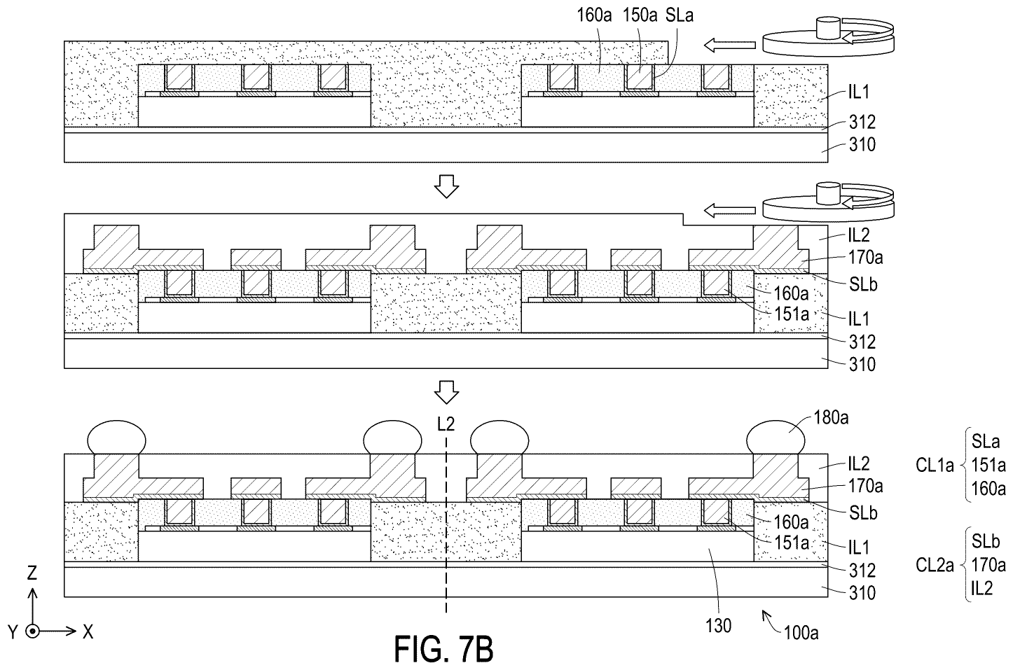

FIG. 7A to FIG. 7B are cross-sectional views of steps S6 to S7 of the method of manufacturing the electronic device of the second embodiment of the disclosure. FIG. 7A to FIG. 7B are steps subsequent to those of FIG. 2 to FIG. 4 and replacing those of FIG. 6A to FIG. 6C. The same or similar members in the embodiment of FIG. 7A to FIG. 7B and the embodiment of FIG. 6A to FIG. 6C adopt the same materials or methods, so the following description of the same and similar portions in the two embodiments is not repeated, and description is directed mainly to the differences between the two embodiments. Referring to FIG. 7A to FIG. 7B and FIG. 6A to FIG. 6C at the same time, an electronic device 100a of the present embodiment is similar to the electronic device 100 of FIG. 6A to FIG. 6C, but the difference between the two is that in the electronic device 100a of the present embodiment, a circuit layer CL1a and a circuit layer CL2a are fan-out circuit designs.

Referring to FIG. 7A, at least one circuit layer CL1a is formed on the transparent carrier 110, and the at least one circuit layer CL1a may be electrically connected to the sample 130. Specifically, the patterned dielectric layer 140a is first formed on the sample 130. The dielectric layer 140a may expose the at least one pad 134 of the sample 130. Next, an insulating layer 160a is formed on the dielectric layer 140a and in the gap G1. In particular, the insulating layer 160a has an opening 161a, and the opening 161a may expose the pad 134. Next, a seed layer SLa and a connection unit 151a are formed in the opening 161a. In particular, the seed layer SLa may be in contact with the pad 134 of the sample 130 to be electrically connected to the sample 130. At this point, the circuit layer CL1a (including the seed layer SLa, the connection unit 151a, and the insulating layer 160a) is formed on the dielectric layer 140a and the pad 134.

Then, please continue to refer to FIG. 7A, a singulation step is performed on the sample 130 (e.g., a wafer) to obtain a plurality of known good chips Cla. Specifically, the singulation step may include: a step of removing the transparent carrier 110 and the adhesive layer 120, and a step of cutting along the cutting line L1 into known good chips Cla.

Then, referring to FIG. 7B, at least one circuit layer CL2a is formed on the circuit layer CL1a, and the at least one circuit layer CL2a may be electrically connected to the sample 130 via the circuit layer CL1a. In particular, the circuit layer CL1a is located between the circuit layer CL2a and the sample 130. Specifically, first, two cut chips Cla are transferred to the carrier 310 having the release layer 312, and the insulating layer IL1 is formed on the chips Cla. In particular, the two chips Cla are disposed on the release layer 312 in a flip-chip manner. The insulating layer IL1 may surround the chips Cla. Next, a portion of the insulating layer IL1 is removed by a method such as grinding to expose the connection unit 151a and the insulating layer 160a. Next, a seed layer SLb is formed on the insulating layer IL1. In particular, the seed layer SLb may be in contact with the connection unit 151a to be electrically connected to the circuit layer CL1a. Next, a conductive layer 170a is formed on the seed layer SLb, and the insulating layer IL2 is formed on the conductive layer 170a. In particular, the insulating layer IL2 may cover the insulating layer IL1, the insulating layer 160a, and the conductive layer 170a. Next, a portion of the insulating layer IL2 is removed by a method such as grinding to expose the conductive layer 170a. By now, the circuit layer CL2a (including the seed layer SLb, the conductive layer 170a, and the insulating layer IL2) is formed on the circuit layer CL1a.

Next, a connection member 180a is formed on the conductive layer 170a. In particular, the connection member 180a may be in contact with the conductive layer 170a. A portion of the connection member 180a may not be overlapped with the sample 130 in the direction Z.

Then, please continue to refer to FIG. 7B, the transparent carrier 310 and the release layer 312 are removed and cut into a plurality of electronic devices 100a along the cutting line L2.

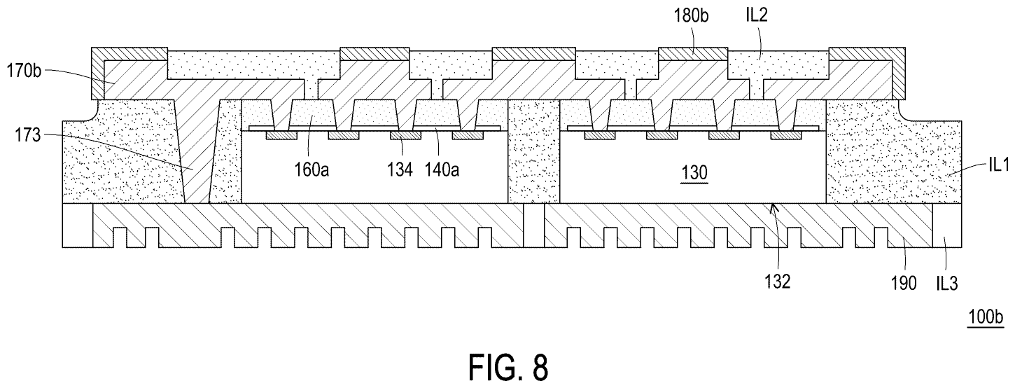

FIG. 8 is a schematic cross-sectional view of the electronic device of the third embodiment of the disclosure. Referring to FIG. 8 and FIG. 7B at the same time, an electronic device 100b of the present embodiment is similar to the electronic device 100a of FIG. 7B, but the difference between the two is that the electronic device 100b of the present embodiment further includes a heat dissipation layer 190, an insulating layer IL3, and a via 173.

Specifically, referring to FIG. 8, the method of manufacturing the electronic device 100b further includes: removing a portion of the insulating layer IL1 by a method such as grinding to expose the surface 132 of the sample 130.

The heat dissipation layer 190 is disposed on the surface 132 of the sample 130. The insulating layer IL3 is disposed on the surface 132 of the sample 130 and surrounds the heat dissipation layer 190.

The via 173 penetrates the insulating layer IL1 and is respectively connected to a conductive layer 170b and the heat dissipation layer 190.

A connection member 180b may also be a solder pad or chemical nickel gold, but the disclosure is not limited thereto.

Based on the above, in an electronic device of an embodiment of the disclosure, by setting a gap between the side surface of the sample and the inner wall of the accommodation space, the issue of cracks caused by excessive step during the subsequent forming of the dielectric layer may be reduced, or the probability of collision between the sample and the transparent carrier may be reduced, thereby improving process yield or reliability. By shortening the step between the surface of the sample and the surface of the transparent carrier, the issue of cracks caused by excessive step during the subsequent forming of the dielectric layer may be reduced, thereby improving process yield or reliability. By correcting the offset, the accuracy of the alignment may be improved, thereby improving process yield or reliability.

Lastly, it should be noted that the above embodiments are used to describe the technical solution of the disclosure instead of limiting it. Although the disclosure has been described in detail with reference to each embodiment above, those having ordinary skill in the art should understand that the technical solution recited in each embodiment above may still be modified, or some or all of the technical features thereof may be equivalently replaced. These modifications or replacements do not make the essence of the corresponding technical solutions depart from the scope of the technical solution of each embodiment of the disclosure.

What is claimed is:

1. A method of manufacturing an electronic device, comprising:
providing a transparent carrier having an accommodation space, wherein the transparent carrier has a first mark;
providing and disposing a sample in the accommodation space of the transparent carrier, wherein the sample has a second mark;
calculating an offset of the sample according to the first mark, the second mark, and a standard value; and
forming a third mark on the sample according to the offset.

2. The method of manufacturing of claim 1, further comprising:
providing a dielectric layer on the sample and the transparent carrier; and
removing the transparent carrier.

3. The method of manufacturing of claim 2, further comprising:
performing a patterning step on the dielectric layer via the third mark to expose at least one pad of the sample.

4. The method of manufacturing of claim 1, wherein the sample comprises a wafer.

5. The method of manufacturing of claim 4, further comprising:
performing a singulation step on the wafer to obtain a plurality of known good chips.

6. The method of manufacturing of claim 1, wherein the transparent carrier comprises a glass.

7. The method of manufacturing of claim 1, wherein a ratio of a coefficient of thermal expansion of the transparent carrier to a coefficient of thermal expansion of the sample is between 0.7 and 3.

8. The method of manufacturing of claim 1, wherein a roughness of a bottom surface of the accommodation space is different from a roughness of a surface of the transparent carrier.

9. The method of manufacturing of claim 1, wherein a roughness of a bottom surface of the accommodation space is less than or equal to 20 microns.

10. The method of manufacturing of claim 1, wherein when the offset is not equal to 0, the third mark is not overlapped with the second mark.

11. A method of manufacturing an electronic device, comprising:
providing a transparent carrier having an accommodation space, and the transparent carrier has a first mark;
disposing a sample in the accommodation space of the transparent carrier, and the sample has a second mark;
calculating an offset of the sample according to the first mark, the second mark, and a standard value; and
forming a third mark on the transparent carrier according to the offset.

12. The method of manufacturing of claim 11, further comprising:
providing a dielectric layer on the sample and the transparent carrier; and
removing the transparent carrier.

13. The method of manufacturing of claim 12, further comprising:
performing a patterning step on the dielectric layer via the third mark to expose at least one pad of the sample.

14. The method of manufacturing of claim 11, wherein the sample comprises a wafer.

15. The method of manufacturing of claim 14, further comprising:
performing a singulation step on the wafer to obtain a plurality of known good chips.

16. The method of manufacturing of claim 11, wherein the transparent carrier comprises a glass.

17. The method of manufacturing of claim 11, wherein a ratio of a coefficient of thermal expansion of the transparent carrier to a coefficient of thermal expansion of the sample is between 0.7 and 3.

18. The method of manufacturing of claim 11, wherein a roughness of a bottom surface of the accommodation space is different from a roughness of a surface of the transparent carrier.

19. The method of manufacturing of claim 11, wherein a roughness of a bottom surface of the accommodation space is less than or equal to 20 microns.

20. The method of manufacturing of claim 11, wherein when the offset is not equal to 0, the third mark is not overlapped with the second mark.
